(19) United States
(12) Patent Application Publication
(10) Pub. No.: US 2025/0150017 A1
(43) Pub. Date: May 8, 2025

(54) POWER TOOL SYSTEM AND DETECTION METHOD

(71) Applicant: JIANGSU DONGCHENG TOOLS TECHNOLOGY CO., LTD, NANTONG (CN)

(72) Inventor: Jie YANG, NANTONG (CN)

(73) Assignee: JIANGSU DONGCHENG TOOLS TECHNOLOGY CO., LTD., NANTONG (CN)

(21) Appl. No.: 18/837,570

(22) PCT Filed: Jun. 29, 2023
(86) PCT No.: PCT/CN2023/103581

§ 371 Date: Aug. 9, 2024

(30) Foreign Application Priority Data
Oct. 29, 2022 (CN) 202211340681.7

(51) Int. Cl. H02P 29/024; B25F 5/02

(52) U.S. Cl. CPC H02P 29/026; B25F 5/02

(57) ABSTRACT

A power tool system includes: a switch; a motor connected to the switch; a control module connected to the motor; a communication module of a power tool connected to the control module; a power supply module of the power tool connected to the control module; and a battery pack configured to supply power to the power supply module of the power tool. The battery pack comprises a communication module. The control module is configured to: receive a conduction signal of the switch; control the motor to operate according to the conduction signal; detect an operation time of the motor; control the communication module of the power tool and the communication module of the battery pack to establish communication therebetween, in response to the operation time being a first predetermined time, enabling the power tool to obtain a state of the battery pack.

### CROSS REFERENCE TO RELATED APPLICATIONS

This application is a 35 U.S.C. § 371 National Phase conversion of International (PCT) Patent Application No. PCT/CN2023/103581 filed on Jun. 29, 2023, which claims priorities to Chinese Patent Applications No. 202211340681.7, filed on Oct. 29, 2022, the content of which are herein incorporated by reference in their entireties.

### TECHNICAL FIELD

The present disclosure relates to the field of power tools, and in particular to a power tool system and a detection method.

### BACKGROUND

A power tool in the art, such as an impact drill, an impact wrench and other cordless power tools, is arranged with a rechargeable battery pack, serving as a power source. As power tools are widely used, functional demands for the battery pack are increasingly higher and diversified. A user may prefer a battery pack having a communication capability. When the users uses the power tool normally, a switch is firstly pressed, and a controller arranged in the power tool detects a conduction signal of the switch and a signal of a communication port of the battery pack. In a case that the power tool is at a low temperature or at a high current, a large current is generated instantly when the power tool is started, a voltage of the battery pack voltage is instantly reduced, and a chip arranged in the battery pack is automatic reset. When the controller in the power tool cannot detect the signal of the communication port of the battery pack or detected that the signal of the communication port is abnormal, it is firstly determined that the signal of the communication port of the battery pack is abnormal, such that the power tool is not allowed to operate. The user may mistakenly believe that the power tool is malfunctioned, and the usage experience is affected.

According to the Chinese Patent Publication No. CN111409044A, published on Jul. 14, 2020, a power tool is disclosed. The battery pack is configured in the power tool. The user presses an operation mechanism. A trigger switch SW coupled with the operation mechanism is triggered to a conducted state. The battery pack provides power to a power supply module of the tool, such that the power is provided to a communication module of the power tool. After the communication module of the power tool is supplied with power, a power activation signal is output to the communication module of the battery pack. The communication module of the power tool transmits the received signal to the control module of the battery pack. The control module of the battery pack controls, according to the signal, a power capacity displaying module of the battery pack. The manner in which the signal of the battery pack being detected firstly and controlling the tool to operate subsequently may cause the user to mistakenly believe that the tool is malfunctioned due to the battery pack being abnormal, affecting the usage experience.

Therefore, an improved power tool system and a detection method need to be provided to overcome defects in the art.

### SUMMARY OF THE DISCLOSURE

For the deficiencies in the art, the present disclosure provide a power tool system and a detection method in which the power tool is controlled to operate firstly, and the signal of the battery pack is detected subsequently, in order to control communication of the power tool and the battery pack.

The present disclosure provides a power tool system, including: a switch; a motor connected to the switch; a control module of a power tool connected to the motor; a communication module of a power tool connected to the control module of the power tool; a power supply module of the power tool connected to the control module of the power tool; a storage module, configured to store a predetermined time in advance; and a battery pack configured to supply power to the power supply module of the power tool. The battery pack includes a communication module. The control module of the power tool is configured to: receive a conduction signal of the switch; detect the conduction signal to control the motor to operate; detect an operation time of the motor; and control the communication module of the power tool and the communication module of the battery pack to establish communication there between, in response to the operation time being a predetermined time, enabling the power tool to obtain a state of the battery pack.

In some embodiments, the state of the battery pack includes: the battery pack operating normally; and the battery pack being malfunctioned.

In some embodiments, the power tool further comprises a positive-electrode terminal, a negative-electrode terminal, and a communication terminal; the battery pack further comprises a positive-electrode power terminal, a negative-electrode power terminal, and a communication terminal. The power tool is connected to the battery pack by enabling the positive-electrode terminal of the power tool to be connected to the positive-electrode power terminal of the battery pack and enabling the negative-electrode terminal of the power tool to be connected to the negative-electrode power terminal of the battery pack, and battery pack is configured to supply power to the power tool. The battery pack is configured to establish the communication by enabling the communication terminal of the battery pack to be connected to the communication terminal of the power tool.

In some embodiments, the control module of the power tool is configured to control the motor to continue operating in response to detecting that a signal of the communication terminal of the battery pack is normal. The control module of the power tool is configured to control the motor to stop operating in response to detecting that the signal of the communication terminal of the battery pack is abnormal.

In some embodiments, the control module of the power tool is configured to control the motor to continue operating in response to detecting that a signal of the communication terminal of the battery pack is normal; the control module of the power tool is configured to control the motor to stop operating in response to detecting no signal of the communication terminal of the battery pack.

The present disclosure further provides a detection method applied by a power tool. The power tool comprises a switch; and a motor connected to the switch; the power tool is connected to a battery pack, the battery pack is configured to supply power to the power tool; the method comprises: setting a predetermined time in advance;
detecting a conduction signal of a switch;
controlling a motor to operate according to the conduction signal; and
detecting an operation time of the motor; and detecting a signal of the battery pack, in response to the operation time being the predetermined time, so as to determine a state of the battery pack based on the signal of the battery pack.

In some embodiments, the state of the battery pack includes: the battery pack operating normally; and the battery pack being malfunctioned.

The present disclosure further provides a power tool system, including:
a storage module, configured to store a predetermined time in advance;
a detection module, configured to detect a conduction signal of a switch;
a control module of a power tool, configured to: control, after receiving the conduction signal of the switch, a motor to operate; detect an operation time of the motor; and detect a signal of a battery pack, in response to the operation time being the predetermined time, so as to determine a state of the battery pack based on the signal of the battery pack.

In some embodiments, the state of the battery pack includes: the battery pack operating normally; and the battery pack being malfunctioned.

In some embodiments, the power tool system further includes a positive-electrode power terminal of the battery pack, a negative-electrode power terminal of the battery pack, a CO port of the battery pack, and a DO port of the battery pack; wherein, the battery pack takes the positive-electrode power terminal and the negative-electrode power terminal to connect to the power tool to provide power to the power tool.

In some embodiments, the control module of the power tool is configured to detect a high level signal and a low level signal at the DO port of the battery pack. The control module of the power tool is configured to control the power tool to continue operating in response to detecting the DO port of the battery pack being at the low level signal. The control module of the power tool is configured to control the power tool to stop operating in response to detecting the DO port of the battery pack being at the high level signal.

In some embodiments, the control module of the power tool is configured to detect a high level signal and a low level signal at the DO port of the battery pack. The control module of the power tool is configured to control the power tool to continue operating in response to detecting the DO port of the battery pack being at the low level signal. The control module of the power tool is configured to control the power tool to stop operating in response to detecting no signal at the DO port of the battery pack.

In some embodiments, power tool system further includes: a positive-electrode power terminal of the battery pack, a negative-electrode power terminal of the battery pack, and a COM port of the battery pack; wherein, the battery pack takes the positive-electrode power terminal and the negative-electrode power terminal to connect to the power tool to supply power to the power tool.

In some embodiments, the control module of the power tool is configured to detect COM port information of the battery pack; the control module of the power tool is configured to control the power tool to continue operating in response to detecting that the COM port information of the battery pack is normal; the control module of the power tool is configured to control the power tool to stop operating in response to detecting that the COM port information of the battery pack is abnormal.

In some embodiments, in response to detecting that the COM port information of the battery pack is normal, the power tool is configured to establish communication with the battery pack to obtain the state of the battery pack.

In some embodiments, the COM port information of the battery pack detected by the control module of the power tool is a voltage of the COM port of the battery pack.

In some embodiments, the normal COM port information of the battery pack is that the voltage of the COM port of the battery pack is within a predetermined operating voltage range.

In some embodiments, the COM port information of the battery pack being abnormal is that the voltage of the COM port of the battery pack is greater than an upper limit of the predetermined operating voltage range or lower than a lower limit of the predetermined operating voltage range.

In some embodiments, the control module of the power tool is configured to detect COM port information of the battery pack; the control module of the power tool is configured to control the power tool to continue operating in response to detecting that the COM port information of the battery pack is normal; and the control module of the power tool is configured to control the power tool to stop operating in response to detecting no COM port information of the battery pack.

According to the present disclosure, the control module of the power tool receives the conduction signal of the switch, controls the motor to operate according to the conduction signal, detects the operation time of the motor. When the operation time is a predetermined time, the control module of the power tool controls the communication module of the power tool and the communication module of the battery pack to establish communication therebetween in order to obtain the state of the battery pack. The power tool is controlled to operate firstly, and the signal of the battery pack is detected subsequently, in order to control the communication module of the power tool and the communication module of the battery pack to establish communication therebetween, such that the state of the battery pack is obtained. In this way, the situation in which the user, when using the tool, mistakenly believes that the tool is malfunctioned due to the battery pack being malfunctioned, can be avoided, and the usage experience is improved.

### BRIEF DESCRIPTION OF THE DRAWINGS

Specific embodiments of the present disclosure are described in further detail below by referring to the accompanying drawings.

FIG. 1 is a structural schematic view of the entire power tool according to an embodiment of the present disclosure.

FIG. 2 is a schematic view of a battery pack according to an embodiment of the present disclosure.

FIG. 3 is a circuit diagram of the power tool according to an embodiment I of the present disclosure.

FIG. 4 is a circuit diagram of the power tool according to an embodiment II of the present disclosure.

### DETAILED DESCRIPTION

The present disclosure is described in further detail below by referring to the accompanying drawings and embodiments.

Terms used in the present disclosure are used for the purpose of describing particular embodiments and are not intended to limit the present disclosure. Terms, such as “up”, “down”, “front”, “rear”, and the like, which indicate orientation or positional relationships, are only used based on the orientation or positional relationships shown in the accompanying drawings. The terms are used only for the purpose of facilitating and simplifying the description of the present disclosure, and are not intended to indicate or imply that the device/element referred to must have a particular orientation or be configured and operated in a particular orientation. Therefore, the terms shall not be interpreted as a limitation of the present disclosure.

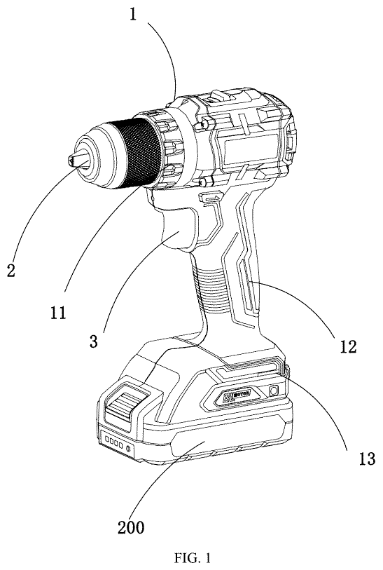

As shown in FIG. 1, a power tool 100 is provided and is configured to be inserted with an operating head (not shown). In the present embodiment, the power tool 100 is an impact drill including a shell 1, a motor (not shown) arranged inside the shell 1, and an output head 2 driven by the motor. The output head 2 is partially exposed from a front end of the shell 1 and is connected to the operating head. The shell 1 includes a body portion 11 extending in an axial direction, a hand-held portion 12 connected to a lower portion of the body portion 11, and a bottom portion 13 disposed at a lower end of the hand-held portion 12. The motor and the output head 2 are arranged inside the body portion 11, and the output head 2 is partially exposed from the front end of the body portion 11. The hand-held portion 12 is configured to held by the user during operation and is arranged with a switch 3. The switch 3 is a trigger, a button, and so on, and is operated by the user to control the power tool 100 to start or stop operating. In the present embodiment, the switch 3 is a trigger. The bottom portion 13 is connected to a battery pack 200 in an insertion manner. The battery pack 200 is configured to provide power for the power tool 100.

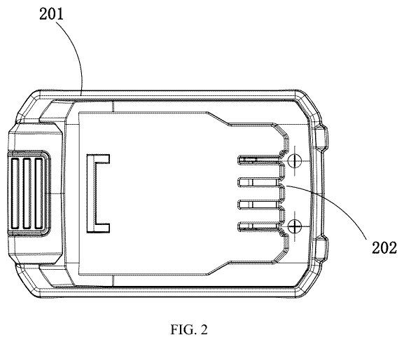

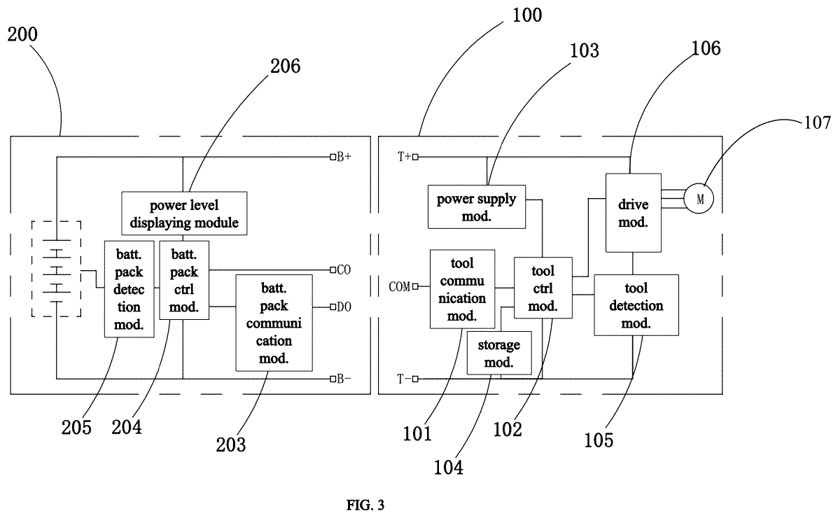

As shown in FIGS. 2 and 3, a diagram of the battery pack a circuit diagram of the power tool of the present disclosure are shown. The battery pack 200 includes a shell 201 and an electric cell group (not shown). The cell group includes a plurality of electric cells (not shown). The plurality of electric cells are electrically connected to each other to form the electric cell group. The electric cell group is arranged inside the shell 201 of the battery pack. A coupling portion 202 is formed on the shell 201 of the battery pack. The coupling portion 202 is connected with the bottom portion 13 of the power tool 100 to enable the battery pack 200 to be mounted to the power tool 100. The battery pack 200 further includes a positive-electrode power terminal B+, a negative-electrode power terminal B−, a CO port, a communication module 203 of the battery pack, a control module 204 of the battery pack connected to the communication module 203 of the battery pack, a detection module 205 of the battery pack connected to the control module 204 of the battery pack, and a power capacity displaying module 206 connected to the control module 204 of the battery pack. The power tool 100 further includes a positive-electrode terminal T+, a negative-electrode terminal T−, a communication module 101 of the power tool, a control module 102 of the power tool connected to the communication module 101 of the power tool, a power supply module 103 supplying power to the control module 102 of the power tool, a storage module 104 connected to the control module 102 of the power tool, a detection module 105 of the tool detecting a parameter of the motor 107, and a drive module 106 driving the motor 107. The communication module 101 of the power tool includes a communication terminal COM. The communication module 203 of the battery pack includes a communication terminal DO. The communication module 101 of the power tool and the communication module 203 of the battery pack establish communication therebetween through the communication terminal COM and the communication terminal DO of the battery pack.

The positive-electrode power terminal B+ and the negative-electrode power terminal B− of the battery pack are connected to the positive-electrode terminal T+ and the negative-electrode terminal T− of the power tool 100, respectively, in order to transmit electric energies. The DO port of the battery pack 200 is connected to the communication terminal COM of the power tool to transmit electrical signals. The power capacity displaying module 206 is configured to display a power capacity of the battery pack 200. The control module 204 of the battery pack is configured to control the power capacity displaying module 206 to display the power capacity of the battery pack 200. The detection module 205 of the battery pack is configured to detect an electrical parameter of the battery pack 200. The control module 204 of the battery pack outputs, based on the electrical parameter of the battery pack 200 detected by the detection module 205 of the battery pack, an electrical signal to the power tool 100 through the DO port. The power tool 100 receives the electrical signal through the COM port and executes related operations. The electrical parameter includes a temperature, a voltage, a current, and so on, of the battery pack 200.

For example, the control module 204 of the battery pack stores a temperature threshold in advance. After the battery pack 200 is mounted to the power tool 100, and when the detection module 205 of the battery pack detects that the temperature of the battery pack 200 is greater than the temperature threshold, a high level signal is output to the power tool 100. The control module 102 of the power tool receives the high level signal, over-temperature protection is performed, and the motor 107 is controlled to stop operating.

In another embodiment, the control module 204 of the battery pack stores a voltage threshold for one electric cell of the plurality of cell groups in advance. After the battery pack 200 is mounted to the power tool 100, and when the detection module 205 of the battery pack detects that a voltage of one cell is lower than the voltage threshold, a high level signal is output to the power tool 100, and the control module 102 of the power tool receives the high level signal, undervoltage protection is performed, and the motor 107 is controlled to stop operating.

In the present embodiment, when the battery pack 200 is assembled to the power tool 100 and the trigger 3 is conducted, the battery pack 200 takes the positive-electrode power terminal B+ and the negative-electrode power terminal B− to connect to the positive-electrode terminal T+ and the negative-electrode terminal T− of the power tool 100 to supply power to the power tool 100. A power supply current of the battery pack 200 is transmitted to the control module 102 of the power tool via the power supply module 103 arranged in the power tool 100. After the control module 102 of the power tool is supplied with power, the control module 102 of the power tool controls the drive module 106 to drive the motor 107. The storage module 104 stores a predetermined time T in advance. The control module 102 of the power tool controls the drive module 106 to drive the motor 107 to operate for a predetermined time T. Subsequently, The communication terminal COM of the power tool 100 detects the high level signal and a low level signal of the communication terminal DO of the battery pack. When the control module 102 of the power tool detects the communication terminal DO of the battery pack being at the low level signal, the control module 102 of the power tool controls the drive module 106 to drive the motor 107 to continue operating, the power tool 100 establishes communication with the battery pack 200, and the power tool 100 obtains a state of the battery pack 200. When the control module 102 of the power tool detects the communication terminal DO of the battery pack being at the high level signal, the control module 102 of the power tool controls the drive module 106 to stop driving the motor 107, the power tool 100 does not establish communication with the battery pack 200, and the power tool does not obtain the state of the battery pack 200. When the control module 102 of the power tool 100 cannot detect the signal from the communication terminal DO of the battery pack, the control module 102 of the power tool controls the drive module 106 to stop driving the motor 107, the power tool 100 does not establish communication with the battery pack 200, the power tool 100 does not obtain the state of the battery pack 200. Specifically, the state of the battery pack 200 refers to: the battery pack 200 operating normally; or the battery pack 200 being malfunctioned. That is, through communication between the power tool 100 and the battery pack 200, the power tool 100 can confirm that the battery pack 200 is operating normally or is malfunctioned. In some embodiments, the state of the battery pack 200, i.e., the battery pack 200 operating normally or being malfunctioned, is determined based on the electrical parameters of the battery pack 200, such as the temperature, the voltage, and the current of the battery pack 200.

According to the power tool in the present disclosure, after the control module 102 of the power tool controls the motor 107 to operate for the predetermined time T, it is detected, through the communication terminal COM of the power tool, whether the communication terminal DO of the battery pack is at the high level signal or the low level signal. When the control module 102 of the power tool detects that the communication terminal DO of the battery pack is at the low level signal, the control module 102 of the power tool controls the motor 107 to continue operating, the power tool establishes communication with the battery pack, and the state of the battery pack is obtained. When the control module 102 of the power tool detects that the communication terminal DO of the battery pack is at the high level signal or no signal from the communication terminal DO of the battery pack is detected, the control module 102 of the power tool controls the motor 107 to stop operating, the power tool does not establish communication with the battery pack, and the state of the battery pack is not obtained. In the present disclosure, the power tool is controlled to operate firstly, and subsequently, the signal of the battery pack is detected, in order to control the communication between the power tool and the battery pack to obtain the state of the battery pack. In this way, the situation in which the user, when using the power tool, mistakenly believes that the power tool is malfunctioned due to the battery pack being malfunctioned, can be avoided, and the usage experience is improved.

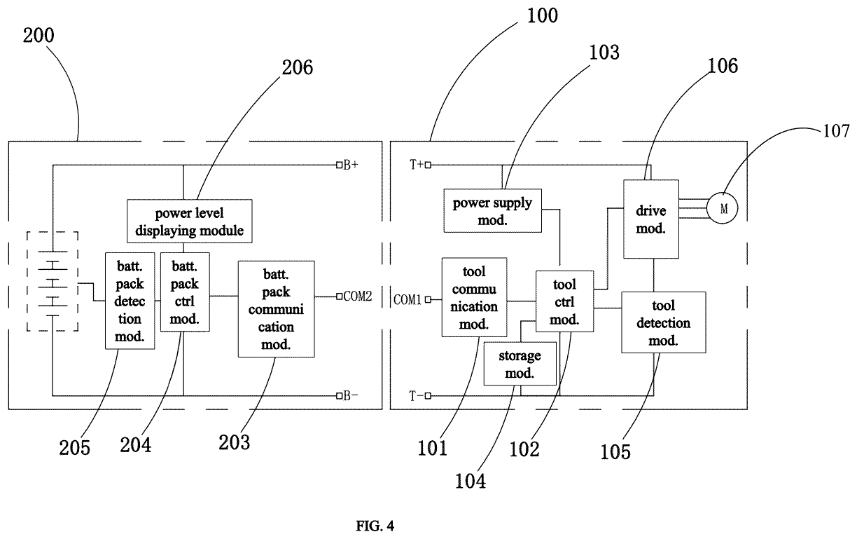

As shown in FIG. 4, a circuit diagram of the power tool of an embodiment II of the present disclosure is shown. In the present embodiment, the battery pack 200 further includes the positive-electrode power terminal B+, the negative-electrode power terminal B−, the communication module 203 of the battery pack, the control module 204 of the battery pack connected to the communication module 203 of the battery pack, the detection module 205 of the battery pack connected to the control module 204 of the battery pack, and the power capacity displaying module 206 connected to the control module 204 of the battery pack. The power tool 100 further includes the positive-electrode terminal T+, the negative-electrode terminal T−, the communication module 101 of the power tool, the control module 102 of the power tool connected to the communication module 101 of the power tool, the power supply module 103 configured to supply power to the control module 102 of the power tool, the storage module 104 connected to the control module 102 of the power tool, the detection module 105 of the tool configured to detecting the parameter of the motor 107, and the drive module 105 configured to drive the motor 107. The communication module 101 of the power tool includes a communication terminal COM1. The communication module 203 of the battery pack includes a communication terminal COM2. The communication module 101 of the power tool takes the communication terminal COM1 to connect to the communication terminal COM2 of the communication module 203 of the battery pack to establish the communication therebetween.

In the present embodiment, when the battery pack 200 is assembled to the power tool 100 and the trigger 3 is conducted, the battery pack 200 takes the positive-electrode power terminal B+ and the negative-electrode power terminal B− of the battery pack to connect to the positive-electrode terminal T+ and the negative-electrode terminal T− of the power tool, respectively, to supply power to the power tool 100. The power supply current of the battery pack 200 is transmitted, via the power module 103 inside the power tool 100, to the control module 102 of the power tool. After the control module 102 of the power tool is powered, the control module 102 of the power tool controls the drive module 106 to drive the motor 107. The storage module 104 stores the predetermined time T and a normal operating voltage of the battery pack 200 in advance. The normal operating voltage of the battery pack 200 is between a minimum operating voltage Uₘᵢₙ and a maximum operating voltage Uₘₐₓ. The control module 102 of the power tool controls the drive module 106 to drive the motor 107 to operate for the predetermined time T. Subsequently, a voltage of the communication terminal COM2 of the battery pack is detected through the communication terminal COM1 of the power tool 100. When the control module 102 of the power tool detects that the voltage of the communication terminal COM2 of the battery pack is between the minimum operating voltage Uₘᵢₙ and the maximum operating voltage Uₘₐₓ of the battery pack 200, the control module 102 of the power tool controls the drive module 106 to drive the motor 107 to continue operating, the power tool 100 establishes communication with the battery pack 200, and the power tool 100 obtains the state of the battery pack 200. When the control module 102 of the power tool detects that the voltage of the communication terminal COM2 of the battery pack is greater than the maximum operating voltage Uₘₐₓ of the battery pack, the control module 102 of the power tool controls the drive module 106 to stop driving the motor 107, the power tool 100 does not establish communication with the battery pack 200 and does not obtain the state of the battery pack 200. When the control module 102 of the power tool detects that the voltage of the communication terminal COM2 of the battery pack is less than the minimum operating voltage Uₘᵢₙ of the battery pack 200, the control module 102 of the power tool controls the drive module 106 to stop driving the motor 107, the power tool 100 does not establish communication with the battery pack 200 and does not obtain the state of the battery pack 200. When the control module 102 of the power tool does not detect any voltage of the communication terminal COM2 of the battery pack, the control module 102 of the power tool controls the drive module 106 to stop driving the motor 107, the power tool 100 does not establish communication with the battery pack 200 and does not obtain the state of the battery pack 200.

According to the power tool in the present disclosure, after the control module 102 of the power tool controls the motor 107 to operate for the predetermined time T, the voltage of the communication terminal COM2 of the battery pack is detected through the communication terminal COM1 of the power tool. When the control module 102 of the power tool detects that the voltage of the communication terminal COM2 of the battery pack is between the minimum operating voltage Uₘᵢₙ and the maximum operating voltage Uₘₐₓ of the battery pack 200, the control module 102 of the power tool controls the motor 107 to continue operating, the power tool establishes communication with the battery pack and obtains the state of the battery pack. When the control module 102 of the power tool detects that the voltage of the communication terminal COM2 of the battery pack is greater than the maximum operating voltage Uₘₐₓ of the battery pack 200, the control module 102 of the power tool controls the motor 107 to stop operating, the power tool does not establish communication with the battery pack and does not obtain the state of the battery pack. When the control module 102 of the power tool detects that the voltage of the communication terminal COM2 of the battery pack is less than the minimum operating voltage Uₘᵢₙ of the battery pack 200, the control module 102 of the power tool controls the motor 107 to stop operating, the power tool does not establish communication with the battery pack and does not obtain the state of the battery pack. When the control module 102 of the power tool does not detect any voltage of the communication terminal COM2 of the battery pack, the control module 102 of the power tool controls the motor 107 to stop operating, the power tool does not establish communication with the battery pack and does not obtain the state of the battery pack. In this way, the situation in which the user, when using the power tool, mistakenly believes that the power tool is malfunctioned due to the battery pack being malfunctioned, can be avoided, and the usage experience is improved.

The present disclosure is not limited to the specific embodiments described above. Any ordinary skilled person in the art shall understand that there are many other alternatives to the power tool and the control method of the present disclosure, without departing from the principles and scope of the present disclosure. The scope of the present disclosure is subject to the appended claims.

1-10. (canceled)

11. A power tool system, comprising: a switch; a motor connected to the switch; a control module of a power tool connected to the motor; a communication module of a power tool connected to the control module of the power tool; a power supply module of the power tool connected to the control module of the power tool; and a battery pack configured to supply power to the power supply module of the power tool;
the battery pack comprises a communication module;
wherein, the control module of the power tool is configured to: receive a conduction signal of the switch; detect the conduction signal to control the motor to operate; detect an operation time of the motor; control the communication module of the power tool and the communication module of the battery pack to establish communication there between, in response to the operation time being a predetermined time, enabling the power tool to obtain a state of the battery pack.

12. The power tool system according to claim 11, wherein, the state of the battery pack comprises: the battery pack operating normally; and the battery pack being malfunctioned.

13. The power tool system according to claim 11, wherein, the power tool further comprises a positive-electrode terminal, a negative-electrode terminal, and a communication terminal; the battery pack further comprises a positive-electrode power terminal, a negative-electrode power terminal, and a communication terminal;
the power tool is connected to the battery pack by enabling the positive-electrode terminal of the power tool to be connected to the positive-electrode power terminal of the battery pack and enabling the negative-electrode terminal of the power tool to be connected to the negative-electrode power terminal of the battery pack, and battery pack is configured to supply power to the power tool;
the battery pack is configured to establish the communication by enabling the communication terminal of the battery pack to be connected to the communication terminal of the power tool.

14. The power tool system according to claim 12, wherein, the control module of the power tool is configured to control the motor to continue operating in response to detecting that a signal of the communication terminal of the battery pack is normal;
the control module of the power tool is configured to control the motor to stop operating in response to detecting that the signal of the communication terminal of the battery pack is abnormal.

15. The power tool system according to claim 12, wherein, the control module of the power tool is configured to control the motor to continue operating in response to detecting that a signal of the communication terminal of the battery pack is normal;
the control module of the power tool is configured to control the motor to stop operating in response to detecting no signal of the communication terminal of the battery pack.

16. A detection method applied by a power tool, wherein, the power tool comprises a switch; and a motor connected to the switch; the power tool is connected to a battery pack, the battery pack is configured to supply power to the power tool; the method comprises:
setting a predetermined time in advance;
detecting a conduction signal of the switch;
controlling the motor to operate according to the conduction signal;
detecting an operation time of the motor; and detecting a signal of the battery pack, in response to the operation time being the predetermined time, so as to determine a state of the battery pack based on the signal of the battery pack.

17. The detection method according to claim 16, wherein, the state of the battery pack comprises: the battery pack operating normally; and the battery pack being malfunctioned.

18. A power tool system, comprising:
a storage module, configured to store a predetermined time in advance;
a detection module, configured to detect a conduction signal of a switch;
a control module of a power tool, configured to: control, after receiving the conduction signal of the switch, a motor to operate; detect an operation time of the motor; and detect a signal of a battery pack, in response to the operation time being the predetermined time, so as to determine a state of the battery pack based on the signal of the battery pack.

19. The power tool system according to claim 18, wherein, the state of the battery pack comprises: the battery pack operating normally; and the battery pack being malfunctioned.

20. The power tool system according to claim 18, further comprising a positive-electrode power terminal of the battery pack, a negative-electrode power terminal of the battery pack, a CO port of the battery pack, and a DO port of the battery pack; wherein, the battery pack takes the positive-electrode power terminal and the negative-electrode power terminal to connect to the power tool to provide power to the power tool.

21. The power tool system according to claim 20, wherein, the control module of the power tool is configured to detect a high level signal and a low level signal at the DO port of the battery pack;
the control module of the power tool is configured to control the power tool to continue operating in response to detecting the DO port of the battery pack being at the low level signal; and
the control module of the power tool is configured to control the power tool to stop operating in response to detecting the DO port of the battery pack being at the high level signal.

22. The power tool system according to claim 20, wherein, the control module of the power tool is configured to detect a high level signal and a low level signal at the DO port of the battery pack;
the control module of the power tool is configured to control the power tool to continue operating in response to detecting the DO port of the battery pack being at the low level signal; and
the control module of the power tool is configured to control the power tool to stop operating in response to detecting no signal at the DO port of the battery pack.

23. The power tool system according to claim 18, further comprising: a positive-electrode power terminal of the battery pack, a negative-electrode power terminal of the battery pack, and a COM port of the battery pack; wherein, the battery pack takes the positive-electrode power terminal and the negative-electrode power terminal to connect to the power tool to supply power to the power tool.

24. The power tool system according to claim 23, wherein, the control module of the power tool is configured to detect COM port information of the battery pack;
the control module of the power tool is configured to control the power tool to continue operating in response to detecting that the COM port information of the battery pack is normal;
the control module of the power tool is configured to control the power tool to stop operating in response to detecting that the COM port information of the battery pack is abnormal.

25. The power tool system according to claim 24, wherein, in response to detecting that the COM port information of the battery pack is normal, the power tool is configured to establish communication with the battery pack to obtain the state of the battery pack.

26. The power tool system according to claim 24, wherein, the COM port information of the battery pack detected by the control module of the power tool is a voltage of the COM port of the battery pack.

27. The power tool system according to claim 26, wherein, the normal COM port information of the battery pack is that the voltage of the COM port of the battery pack is within a predetermined operating voltage range.

28. The power tool system according to claim 27, wherein the COM port information of the battery pack being abnormal is that the voltage of the COM port of the battery pack is greater than an upper limit of the predetermined operating voltage range or lower than a lower limit of the predetermined operating voltage range.

29. The power tool system according to claim 23, wherein, the control module of the power tool is configured to detect COM port information of the battery pack;
the control module of the power tool is configured to control the power tool to continue operating in response to detecting that the COM port information of the battery pack is normal;
the control module of the power tool is configured to control the power tool to stop operating in response to detecting no COM port information of the battery pack.
